(19) United States
(12) Patent Application Publication
(10) Pub. No.: US 2004/0259379 A1
(43) Pub. Date: Dec. 23, 2004

(54) Low temperature nitridation of silicon

(76) Inventor: Yoshi Ono, Camas, WA (US)

Correspondence Address: David C. Ripma, Patent Counsel, Sharp Laboratories of America, Inc., 5750 NW Pacific Rim Boulevard, Camas, WA, 98607, US

(21) Appl. No.: 10/602,194

(22) Filed: Jun. 23, 2003

(51) Int. Cl. H01L 21/31; H01L 21/8238; H01L 21/469

(52) U.S. Cl. 438/776

(57) ABSTRACT

A method of low-temperature nitridation of a silicon substrate includes placing a silicon wafer in a vacuum chamber on a heated chuck; maintaining the silicon wafer at a temperature of between about room temperature and 400° C.; introducing a nitrogen-containing gas into the vacuum chamber; dissociating the nitrogen-containing gas into nitrogen with a excimer lamp and flowing the nitrogen over the silicon wafer; and forming an silicon nitride layer on at least a portion of the silicon wafer.

### FIELD OF THE INVENTION

This invention relates to the fabrication of integrated circuits on silicon, and specifically to a method of forming a high quality silicon nitride layer at low temperature in an integrated circuit.

### BACKGROUND OF THE INVENTION

Thermally grown silicon nitride films are rarely used in conventional IC fabrication because the temperature required to form a silicon nitride film is higher than that for SiO₂ formation, which higher temperature may result in damage of SiO₂ layers. Instead, either low-pressure chemical vapor deposition (LPCVD) or plasma-enhanced chemical vapor deposition (PECVD) silicon nitride films are typically used. S. K . Gandhi, VLSI Fabrication Principles: Silicon and Gallium Arsenide, 2nd ed., 1994. Silicon nitride, when deposited near the stoichiometric Si₃N₄ composition, exhibits a high density and excellent diffusion barrier properties. There are instances where a good, high quality thin, e.g., between about one nm and 100 nm, silicon nitride layer is desired. One is the top stack of a silicon oxide gate dielectric, to prevent the diffusion of boron from p-type gates into a channel region. Another is as an etch stop, e.g., under a silicon dioxide layer.

The LPCVD technique deposits silicon nitride at a high deposition rate using SiH₄ and NH₃ at temperatures of 700° C. to 900° C. The high deposition rate makes this technique very useful for masking and diffusion blocking applications. The high deposition temperature, however, makes for a high degree of stress in the film when cooled to room temperature. The PECVD technique also has a high deposition rate at temperatures of between about 275° C. to 400° C. Films formed by PECVD have a high quantity of hydrogen incorporated therein and have a higher wet etch rate than a LPCVD film. Another alternative is to reactive sputter silicon nitride with a silicon target and nitrogen in the plasma. Other low temperature methods have been reported, e.g., U.S. Pat. No. 6,274,510 B1, for Lower temperature method for forming high quality silicon nitride dielectrics, granted Aug. 14, 2001, to Wilk et al.

### SUMMARY OF THE INVENTION

A method of low-temperature nitridation of a silicon substrate includes placing a silicon wafer in a vacuum chamber on a heated chuck; maintaining the silicon wafer at a temperature of between about room temperature and 400° C.; introducing a nitrogen-containing gas into the vacuum chamber; dissociating the nitrogen-containing gas into nitrogen with a excimer lamp and flowing the nitrogen over the silicon wafer; and forming an silicon nitride layer on at least a portion of the silicon wafer.

It is an object of the invention to provide a high quality silicon nitride film for use in an integrated circuit.

Another object of the invention is to provide a silicon nitride film which is formed at reactively low temperature.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a schematic representation of the apparatus used to achieve the low temperature nitridation.

FIG. 2 depicts the growth rate of the silicon nitride layer at room temperature and 400° C. chuck temperature.

FIG. 3 depicts the efficacy of the nitride layer in blocking thermal oxidation.

### DETAILED DESCRIPTION OF THE PREFERRED EMBODIMENTS

The method of the invention disclosed herein employs the use of nitrogen radicals to convert silicon to a silicon nitride. The method of the invention can also form a thin nitride layer on an already-grown silicon oxide layer by displacing the oxygen at the top surface and converting at least a portion of silicon oxide to silicon nitride. Because a silicon nitride layer can be formed at a relatively low temperature, the inherent stress level is significantly reduced. This has been reported to have been done with radicals generated in a plasma, K. Watanabe et al., Controlling the concentration and position of nitrogen in ultrathin oxynitride films formed by using oxygen and nitrogen radicals, Appl. Phys. Lett. 76, 2940 (2000). In the method of the invention, it is done without the plasma discharge, which may cause large amounts of silicon damage. The limitation of this technique is that thickness of up to 5 nm is reasonable and thicker films will be nearly impossible to grow unless higher temperatures are employed.

The method of the invention generates large quantities of nitrogen radicals on or near the surface of a silicon layer, or silicon oxide layer which is to be converted to silicon nitride. The radicals are generated by the photolysis of NH₃. The light source used here is a Xe₂ excimer lamp that emits efficiently at a wavelength of 172 nm, or 7.21 eV in energy. The bonding energy for NH₂—H is 4.8 eV, for N—H is 3.3 eV, and NH—H is expected to be somewhere in between these values, so the photon energy is sufficient to cleave the strip the nitrogen in ammonia of it's hydrogen atoms. The ionization potentials of NH₃, NH₂, NH and N are 10.2 eV, 11.4 eV, 13.1 eV and 14.5 eV, respectively, so the formation of ions in the gas phase are improbable.

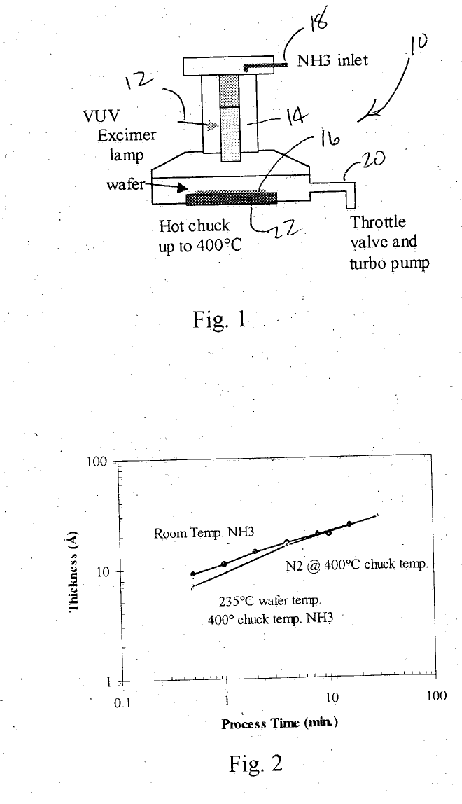

The apparatus used in the method of the invention is depicted in FIG. 1, generally at 10. An excimer lamp 12, which emits light at a wavelength of 172 nm is placed in a vacuum chamber 14 above the surface of silicon wafer 16 that is to be oxidized. Excimer lamp 12 is a xenon-based lamp and is commercially available at a reasonable cost. One such lamp is a Xeradex® lamp produced by Osram Sylvania.

A'steady flow of a nitrogen-containing gas, such as NH₃, is introduced into chamber 14 through inlet 18. The pressure in chamber 14 is controlled by a throttle valve 20, located between the chamber and the pump system. Wafer 16 sits on a heated chuck 22, capable of reaching temperatures of up to about 400° C. The thermal coupling between the wafer and chuck is poor, so the actual wafer temperature may be lower than 250° C. when the chuck temperature is set at 400° C. Chamber pressure is controlled to a range between about five mTorr. to 200 mTorr. The flow of NH₃ is regulated to be between about two sccm and 50 sccm.

Excimer lamp 12 emits at a wavelength of 172 nm. This Xe excimer lamp is commercially available at a reasonable cost. In developing the method of the invention, a Xeradex lamp produced by Osram Sylvania was used. A layer of silicon nitride having a thickness of between six Å and 50 Å may be grown using the method of the invention and apparatus in a time of between about thirty seconds and three hours.

The direct illumination of the wafer surface may generate photoelectrons and a charged surface that may participate in the nitridation process. The work function of silicon is less than 5 eV so electrons can have over 2.2 eV of kinetic energy. Electron attachment of the low energy electrons may generate negatively charged species, such as NH₂⁻, that are quite stable. Adsorbed molecules on the surface of the substrate may also play a role in the nitride layer growth. The growth of the film may be assisted by a field across the growing dielectric layer where a positively charged interface attracts negative ions, similar to the metal oxidation model proposed by Cabrera and Mott in 1948, as reported by J. Joseph et al., A kinetics study of the electron cyclotron resonance plasma oxidation of silicon, J. Vac. Sci. Technol. B10, 611 (1992).

The film growth rates observed do not follow a parabolic function as predicted by Cabrera-Mott, nor by thermal oxidation models. FIG. 2 shows the observed growth rates in the chamber at room temperature, nominally 15° C., and at a chuck temperature of 400° C., which corresponds to a wafer temperature of 235° C., with a chamber pressure of 50 mTorr. Using the method of the invention, growing films thicker than 50 Å will take more than 3 hours, approaching unreasonable lengths of time for the thickness.

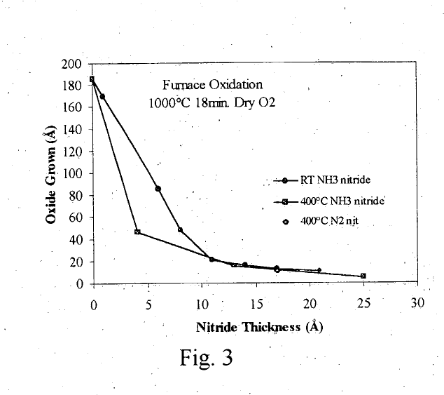

A test of the nitride-like quality is the efficacy to block diffusion at high temperatures. This is demonstrated with the blocking of oxygen during a 1000° C. dry oxidation for 18 minutes. A bare silicon wafer will oxidize to yield a 19 nm silicon dioxide layer. Approximately 1.2 nm of nitride will effectively block oxygen and less than 2.0 nm of oxide will form. This is illustrated in FIG. 3 for the room temperature and 400° C. chuck temperature nitridation process. It is seen that the high temperature nitride is more effective as a diffusion block in the sub-1.0 nm region.

One sample nitrided with N₂ rather than NH₃ is illustrated in FIGS. 2 and 3. The N₂ appears to hold promise as an alternative to NH₃.

With the advancement in excimer lamp technology, the use of alternate wavelengths are possible. Other excimers produce light at 126 nm, 146 nm, 222 nm, and 308 nm, however, these are probably not as efficiently as the Xe₂ at 172 nm.

The configuration of the lamp can be altered to form a ring around the substrate or lie in a different orientation with respect to the substrate. A variety of lamp shapes are possible and can be oriented in a variety of positions to make this process work.

Thus, a method and system for low temperature nitridation of silicon has been disclosed. It will be appreciated that further variations and modifications thereof may be made within the scope of the invention as defined in the appended claims.

I claim:

1. A method of low-temperature nitridation of a silicon substrate comprising:
placing a silicon wafer in a vacuum chamber on a heated chuck;
maintaining the silicon wafer at a temperature of between about room temperature and 400° C.;
introducing a nitrogen-containing gas into the vacuum chamber;
dissociating the nitrogen-containing gas into nitrogen with a excimer tamp and flowing the nitrogen over the silicon wafer; and
forming an silicon nitride layer on at least a portion of the silicon wafer.

2. The method of claim 1 which further includes maintaining the vacuum chamber at a pressure of between about five mTorr. and 200 mTorr.

3. The method of claim 1 wherein said introducing the nitrogen-containing gas in the vacuum chamber includes providing a gas flow rate of between about two sccm and 50 sccm.

4. The method of claim 1 wherein said maintaining includes maintaining the wafer in the vacuum chamber in contact with nitrogen for between about thirty seconds and three hours.

5. The method of claim 1 which includes forming a silicon nitride layer on a silicon wafer having thickness of between about six Å to 50 Å in a time period of between about thirty seconds to three hours.

6. The method of claim 1 wherein the nitrogen-containing gas is taken from the group of gases consisting of N₂, NH₃, NH₂ and NH, and combinations thereof.

7. The method of claim 1 wherein said forming includes providing a positively charged interface across the nitride layer.

8. The method of claim 1 wherein said placing includes placing a silicon wafer having a layer of silicon oxide on the upper surface thereof in a vacuum chamber.

9. A method of low-temperature nitridation of a silicon substrate comprising:
placing a silicon wafer in a vacuum chamber on a heated chuck;
maintaining the silicon wafer at a temperature of between about room temperature and 400° C.;
introducing a nitrogen-containing gas into the vacuum chamber, wherein the nitrogen-containing gas is taken from the group of gases consisting of N₂, NH₃, NH₂ and NH, and combinations thereof;
dissociating the nitrogen-containing gas into nitrogen with a excimer lamp generating light at a wavelength of about 172 nm and flowing the nitrogen over the silicon wafer; and
forming an silicon nitride layer on at least a portion of the silicon wafer.

10. The method of claim 9 which includes forming a silicon nitride layer on a silicon wafer having thickness of between about six Å to 50 Å in a time period of between about thirty seconds to three hours.

11. The method of claim 9 wherein said maintaining includes maintaining the wafer in the vacuum chamber in contact with nitrogen for between about thirty seconds to three hours.

12. The method of claim 9 which further includes maintaining the vacuum chamber at a pressure of between about five mTorr. and 200 mTorr.

13. The method of claim 9 wherein said introducing the nitrogen-containing gas in the vacuum chamber includes providing a gas flow rate of between about two sccm and 50 sccm.

14. The method of claim 9 wherein said forming includes providing a positively charged interface across the nitride layer.

15. The method of claim 9 wherein said placing includes placing a silicon wafer having a layer of silicon oxide on the upper surface thereof in a vacuum chamber.

16. A method of low-temperature nitridation of a silicon substrate comprising:
placing a silicon wafer in a vacuum chamber on a heated chuck;
maintaining the silicon wafer at a temperature of between about room temperature and 400° C.;
providing a positively charged interface across the nitride layer;
introducing a nitrogen-containing gas into the vacuum chamber;
dissociating the nitrogen-containing gas into nitrogen with a excimer lamp and flowing the nitrogen over the silicon wafer; and
forming an silicon nitride layer on at least a portion of the silicon wafer.

17. The method of claim 16 wherein the nitrogen-containing gas is taken from the group of gases consisting of N₂, NH₃, NH₂ and NH, and combinations thereof.

18. The method of claim 16 which further includes maintaining the vacuum chamber at a pressure of between about five mtorr. and 200 mTorr.

19. The method of claim 16 which includes forming a silicon nitride layer on a silicon wafer having thickness of between about six Å to 50 Å in a time period of between about thirty seconds minute to three hours.

20. The method of claim 16 wherein said maintaining includes maintaining the wafer in the vacuum chamber in contact with nitrogen for between about thirty seconds to three hours.

21. The method of claim 16 wherein said introducing the nitrogen-containing gas in the vacuum chamber includes providing a gas flow rate of between about two sccm and 50 sccm.

22. The method of claim 16 wherein said placing includes placing a silicon wafer having a layer of silicon oxide on the upper surface thereof in a vacuum chamber.
